(19) United States
(12) Patent Application Publication
(10) Pub. No.: US 2013/0196512 A1
(43) Pub. Date: Aug. 1, 2013

(54) METHOD AND APPARATUS FOR MANUFACTURING SEMICONDUCTOR DEVICE

(71) Applicants: Tatsuhiko KOIDE, Mie-ken (JP); Yoshihiro OGAWA, Mie-ken (JP); Yoshihiro UOZUMI, Aichi-ken (JP)

(72) Inventors: Tatsuhiko KOIDE, Mie-ken (JP); Yoshihiro OGAWA, Mie-ken (JP); Yoshihiro UOZUMI, Aichi-ken (JP)

(21) Appl. No.: 13/595,076

(22) Filed: Aug. 27, 2012

(30) Foreign Application Priority Data
Jan. 30, 2012 (JP) 2012-017262

(51) Int. Cl. H01L 21/306; B08B 3/00

(52) U.S. Cl. 438/745; 134/105; 257/E21.219

(57) ABSTRACT

According to one embodiment, a method is disclosed for manufacturing a semiconductor device. The method can rinse a substrate with water, a plurality of protruding patterns being formed on the substrate. The method can dry the substrate by removing water from a recess between the protruding patterns by irradiating microwaves.

### CROSS-REFERENCE TO RELATED APPLICATIONS

This application is based upon and claims the benefit of priority from the prior Japanese Patent Application No. 2012-017262, filed on Jan. 30, 2012; the entire contents of which are incorporated herein by reference.

### FIELD

Embodiments described herein relate generally to a method and an apparatus for manufacturing a semiconductor device.

### BACKGROUND

The manufacturing processes of a semiconductor device include various processes such as lithography processes, etching processes, ion implantation processes, etc. After ending each process, and prior to transferring to the next process, a wet cleaning process and a drying process are implemented to clean the front surface of the substrate by removing impurities and/or residue remaining on the front surface of the substrate.

With the downscaling of elements formed in substrates in recent years, a problem occurs where fine resist patterns and device patterns that are formed by lithography processes and etching processes collapse in the wet cleaning process and the drying process.

### BRIEF DESCRIPTION OF THE DRAWINGS

FIGS. 1A and 1B are cross-sectional views of processes, illustrating processes in which protruding patterns are formed in a method for manufacturing a semiconductor device according to a first embodiment;

FIG. 2 is a flowchart illustrating the processes in which the protruding patterns are formed in the method for manufacturing the semiconductor device according to the first embodiment;

FIG. 3 is a flowchart illustrating methods for cleaning and drying a semiconductor member of the method for manufacturing the semiconductor device according to the first embodiment;

FIG. 4 is a cross section SEM (Scanning Electron Microscope) photograph illustrating the collapsed protruding patterns;

FIGS. 5A to 5D are schematic cross-sectional views illustrating a model in which the water is removed in the method for manufacturing the semiconductor device according to the first embodiment;

FIG. 6 is a flowchart illustrating methods for cleaning and drying a semiconductor member of a method for manufacturing a semiconductor device according to a second embodiment;

FIGS. 7A to 7D are schematic cross-sectional views illustrating a model in which the water is removed in the method for manufacturing the semiconductor device according to the second embodiment;

FIGS. 8A and 8B are planar SEM photographs illustrating the protruding patterns of a semiconductor member of the method for manufacturing the semiconductor device;

FIGS. 9A to 9C are planar SEM photographs illustrating protruding patterns of four different locations of the upper surface of the semiconductor member of the method for manufacturing the semiconductor device;

FIGS. 10A and 10B are planar SEM photographs illustrating protruding patterns of four different locations of the upper surface of the semiconductor member of the method for manufacturing the semiconductor device;

FIG. 11 compares the first embodiment, the second embodiment, and the comparative example of the first embodiment of the method for manufacturing the semiconductor device;

FIG. 12 illustrates the apparatus for manufacturing the semiconductor device according to a third embodiment;

FIG. 13 illustrates an apparatus for manufacturing a semiconductor device according to a fourth embodiment;

FIGS. 14A and 14B illustrate an apparatus for manufacturing a semiconductor device according to a fifth embodiment; and

FIG. 15 illustrates an apparatus for manufacturing a semiconductor device according to a sixth embodiment.

### DETAILED DESCRIPTION

In general, according to one embodiment, a method is disclosed for manufacturing a semiconductor device. The method can rinse a substrate with water, a plurality of protruding patterns being formed on the substrate. The method can dry the substrate by removing water from a recess between the protruding patterns by irradiating microwaves.

According to another embodiment, an apparatus for manufacturing a semiconductor device includes a chemical liquid supply unit, a water supply unit and a drying mechanism. The chemical liquid supply unit is configured to supply a chemical liquid to a processing body to clean the processing body. The water supply unit is configured to supply water to the processing body to rinse the processing body. The drying mechanism is configured to remove water from a front surface of the processing body. The drying mechanism includes a microwave irradiation unit configured to irradiate microwaves onto the processing body.

Various embodiments will be described hereinafter with reference to the accompanying drawings.

### First Embodiment

First, a first embodiment will be described.

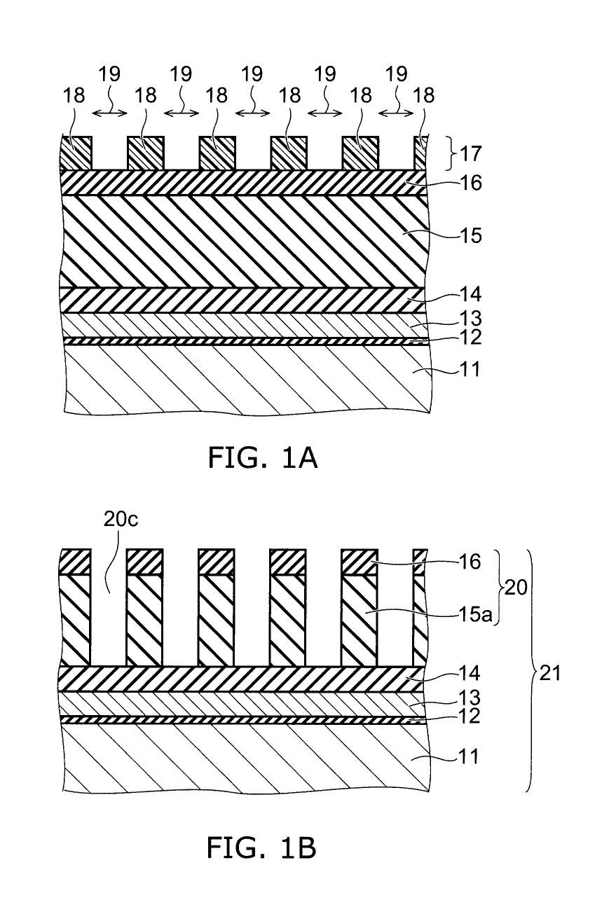

FIGS. 1A and 1B are cross-sectional views of processes, illustrating processes in which protruding patterns are formed in a method for manufacturing a semiconductor device according to the first embodiment.

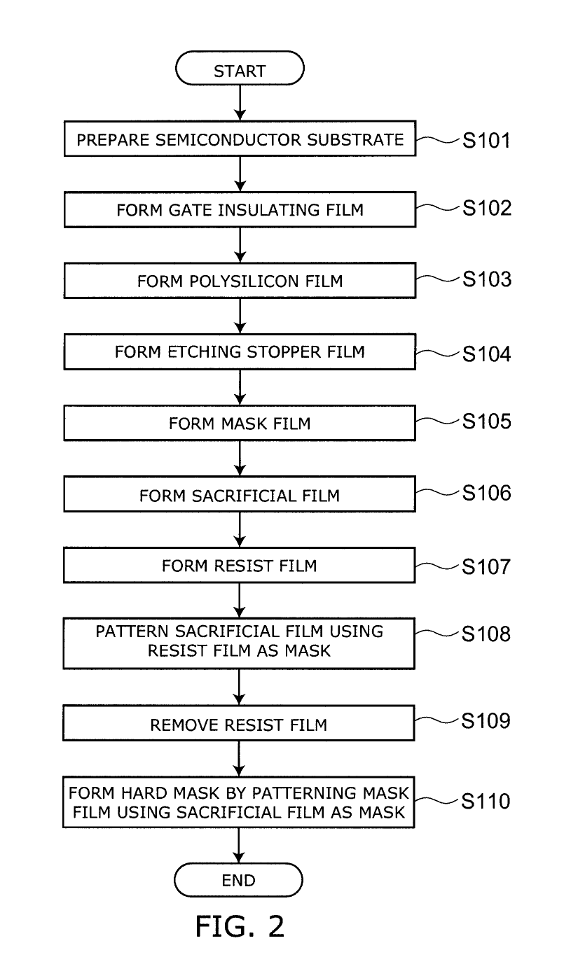

FIG. 2 is a flowchart illustrating the processes in which the protruding patterns are formed in the method for manufacturing the semiconductor device according to the first embodiment.

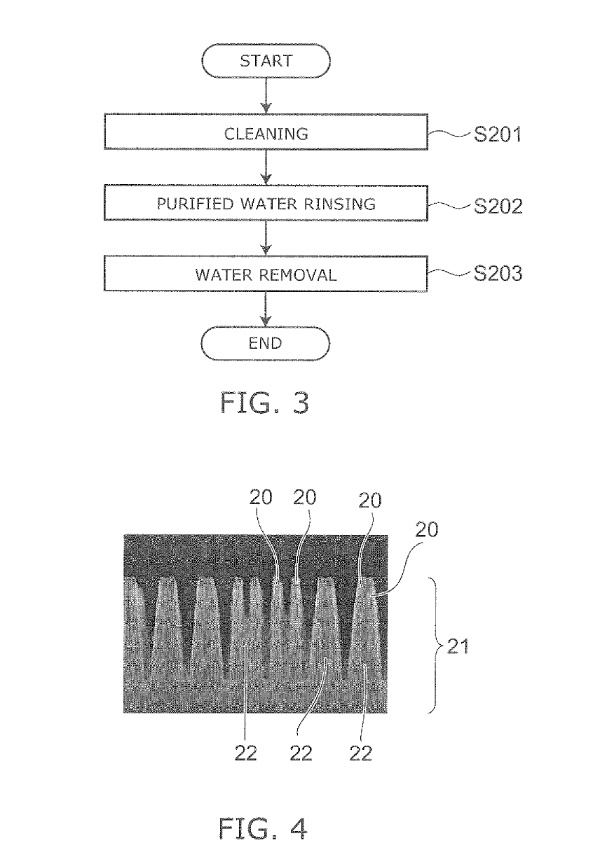

FIG. 3 is a flowchart illustrating methods for cleaning and drying a semiconductor member of the method for manufacturing the semiconductor device according to the first embodiment.

FIG. 4 is a cross section SEM (Scanning Electron Microscope) photograph illustrating the collapsed protruding configuration.

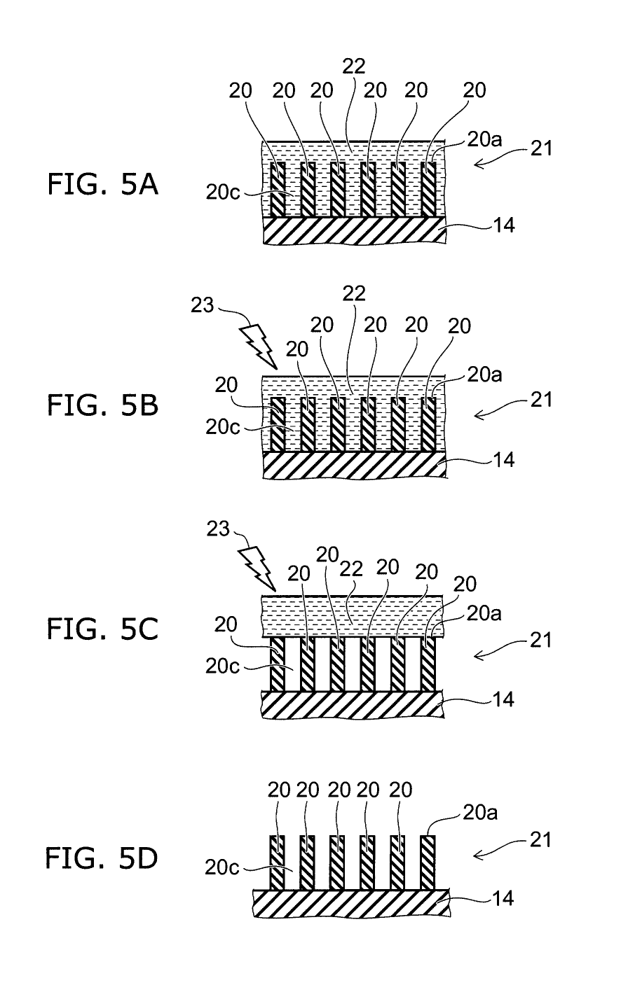

FIGS. 5A to 5D are schematic cross-sectional views illustrating a model in which the water is removed in the method for manufacturing the semiconductor device according to the first embodiment.

First, the process in which the protruding patterns are formed in the method for manufacturing the semiconductor device according to this embodiment will be described.

As illustrated in FIG. 1A and step S101 of FIG. 2, a semiconductor substrate 11, e.g., a silicon substrate, is prepared.

Then, as illustrated in step S102, for example, a silicon oxide film is formed with a film thickness of 5 nm as a gate insulating film 12 on the semiconductor substrate 11.

Continuing as illustrated in step S103, for example, a polysilicon film is formed with a film thickness of 100 nm as a conductive film 13 used to form a gate electrode on the gate insulating film 12. For example, the conductive film 13 is a film used to form a FG (floating gate) electrode of NAND flash memory.

Then, as illustrated in step S104, for example, a silicon nitride film used to form an etching stopper film 14 is formed with a film thickness of 100 nm on the conductive film 13.

Continuing as illustrated in step S105, for example, a silicon oxide film is formed with a film thickness of 250 nm as a mask film 15 used to form a hard mask on the etching stopper film 14

Then, as illustrated in step S106, for example, a sacrificial film 16 is formed with a film thickness of 100 nm on the mask film 15. The sacrificial film 16 is a film made of a material having RIE (reactive ion etching) selectivity with the mask film 15 formed under the sacrificial film 16.

Continuing as illustrated in step S107, a resist film 17 is formed on the sacrificial film 16. The resist film 17 is formed to include multiple patterns 18 having line configurations extending in one direction in a plane parallel to the upper surface of the sacrificial film 16 by using lithography. The spaces between the patterns 18 are called pattern space portions 19. The width of the pattern 18 and the width of the pattern space portion 19 are 20 nm.

Then, as illustrated in step S108, the sacrificial film 16 is patterned by RIE using the resist film 17 in which the patterns 18 are formed as a mask.

Subsequently, as illustrated in step S109, the resist film 17 is removed using SPM (Sulphuric acid Hydrogen Peroxide Mixture) which is a mixed liquid of sulfuric acid and aqueous hydrogen peroxide.

Then, as illustrated in FIG. 1B and step S110 of FIG. 2, the mask film 15 is etched using the sacrificial film 16 as a mask. The etching is stopped at the upper surface of the etching stopper film 14. Thereby, a hard mask 15a is formed from the mask film 15. Protruding patterns 20 including the hard mask 15a and the sacrificial film 16 are formed on the upper surface of the etching stopper film 14. The aspect ratio, which is the ratio of the height to the width, of the protruding patterns 20 is, for example, about 10.

Thus, the protruding patterns 20 are formed on the semiconductor substrate 11. Recesses 20c are between the protruding patterns 20. A semiconductor member 21 is formed of the members formed up to this process, i.e., the semiconductor substrate 11, the gate insulating film 12, the conductive film 13, the etching stopper film 14, and the protruding patterns 20. The semiconductor member 21 includes the semiconductor substrate 11, and the hard mask 15a and the sacrificial film 16 provided on the semiconductor substrate 11. Because dirt such as etching residue, etc., is adhered to the semiconductor member 21, it is necessary to perform cleaning and drying prior to proceeding to the next process.

The methods for cleaning and drying the semiconductor member 21 will now be described.

As illustrated in step S201 of FIG. 3, cleaning of the front surface of the semiconductor member 21 is performed. For example, the cleaning is performed using a chemical liquid (a first chemical liquid) of SPM. Thereby, the etching residue remaining on the front surface of the semiconductor member 21 can be removed. Other than SPM, SC1 which is an alkaline aqueous solution of ammonia and aqueous hydrogen peroxide may be used as the chemical liquid.

Subsequently, as illustrated in step S202, rinsing is performed using purified water, e.g., DIW (deionized water) to remove the chemical liquid adhered to the semiconductor member 21. The rinsing is performed by replacing the chemical liquid adhered to the semiconductor member 21 with the purified water.

Then, as illustrated in step S203, the purified water used in the rinsing is removed.

The method for removing the purified water will now be described. The example illustrated in FIG. 5A to FIG. 5D is but one example of several models in which the water is removed.

As illustrated in FIG. 5A, water 22 remains in the recesses 20c between the protruding patterns 20 of the semiconductor member 21 and on an upper surface 20a of the protruding patterns 20 of the semiconductor member 21 after the rinsing with the purified water.

When the water 22 in the recesses 20c between the protruding patterns 20 evaporates, the water surface of the water in the recesses 20c between the protruding patterns 20 gradually decreases. Due to different heights of the water surface of the water 22 remaining in the recesses 20c, the balance of the forces caused by the capillary forces on the protruding patterns 20 degrades. Thereby, the protruding patterns 20 collapse as illustrated in FIG. 4.

Therefore, as illustrated in FIG. 5B, microwaves 23 are irradiated onto the semiconductor member 21 after the rinsing with the purified water. Thereby, the water 22 on the upper surface 20a of the protruding patterns 20 and the water 22 in the recesses 20c between the protruding patterns 20 are removed. The frequency of the microwaves 23 is 400 MHz to 25 GHz. The microwaves are irradiated with an intensity of, for example, 200 W to 1000 W.

When irradiating the microwaves 23 onto the semiconductor member 21 as illustrated in FIG. 5C, the water 22 in the recesses 20c between the protruding patterns 20 is discharged from the recesses 20c and moves onto the upper surface 20a of the protruding patterns 20. This is considered to have the following model. Supporting results are experimentally observed. For example, the water 22 in the recess rises up so as to be discharged from the recesses 20c as illustrated in FIGS. 5B and 5C when irradiating the microwaves onto the semiconductor member 21 in the state of being wetted with water. As a result, the water 22 that is discharged from the recesses 20c and pushed out onto the upper surface 20a moves onto the upper surface 20a and drops off the semiconductor member 21. Some of the water 22 on the upper surface 20a of the protruding patterns 20 is evaporated by the heating of the microwaves 23.

Thus, as illustrated in FIG. 5D, the semiconductor member 21 is dried by removing the water 22 adhered to the semiconductor member 21.

Effects of this embodiment will now be described.

In the method for manufacturing the semiconductor device according to this embodiment, the microwaves 23 are irradiated onto the semiconductor member 21 after the rinsing with the purified water. Thereby, the water 22 in the recesses 20c between the protruding patterns 20 is discharged from the recesses 20c and moves onto the upper surface 20a of the protruding patterns 20. As a result, the water 22 can be removed without the protruding patterns 20 collapsing. Therefore, even in the case where a hard mask 15a that is fine is formed, the semiconductor device can be downscaled because the collapse of the hard mask 15a can be suppressed.

Although at least a portion of the protruding patterns 20 is formed in the hard mask 15a in this embodiment, this is not limited thereto. If the protruding patterns 20 are patterns having high aspect ratios, the protruding patterns 20 may be patterns formed in the resist film 17 and/or the semiconductor substrate 11.

The purified water rinse process is not limited to being performed after the cleaning process. The purified water rinse process is applicable also when performed after the developing of the lithography process.

### Comparative Example

A comparative example will now be described.

In this comparative example, the water is removed by drying by N₂ blow without irradiating the microwaves. Other than the method for removing the water being drying by N₂ blow, the method for manufacturing the semiconductor device is similar to that of the first embodiment described above.

In the method for manufacturing the semiconductor device according to this comparative example, the semiconductor member 21 is dried by drying by N₂ blow. In the case of drying by N₂ blow or natural drying, the water 22 in the recesses 20c between the protruding patterns 20 does not easily move onto the upper surface 20a of the protruding patterns 20. When the water 22 in the recesses 20c between the protruding patterns 20 evaporates, the amount of the water 22 in the recesses 20c is different between the protruding patterns 20; and the balance of the forces caused by the capillary forces on the protruding patterns 20 degrades. Thereby, there are cases where the protruding patterns 20 collapse. Therefore, it is difficult to downscale the semiconductor device.

### Second Embodiment

A second embodiment will now be described.

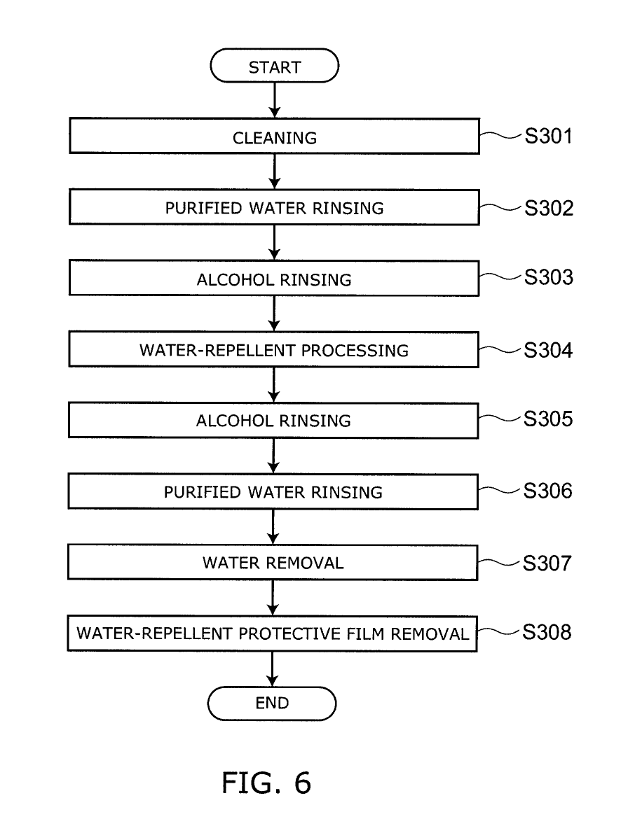

FIG. 6 is a flowchart illustrating methods for cleaning and drying a semiconductor member of a method for manufacturing a semiconductor device according to the second embodiment.

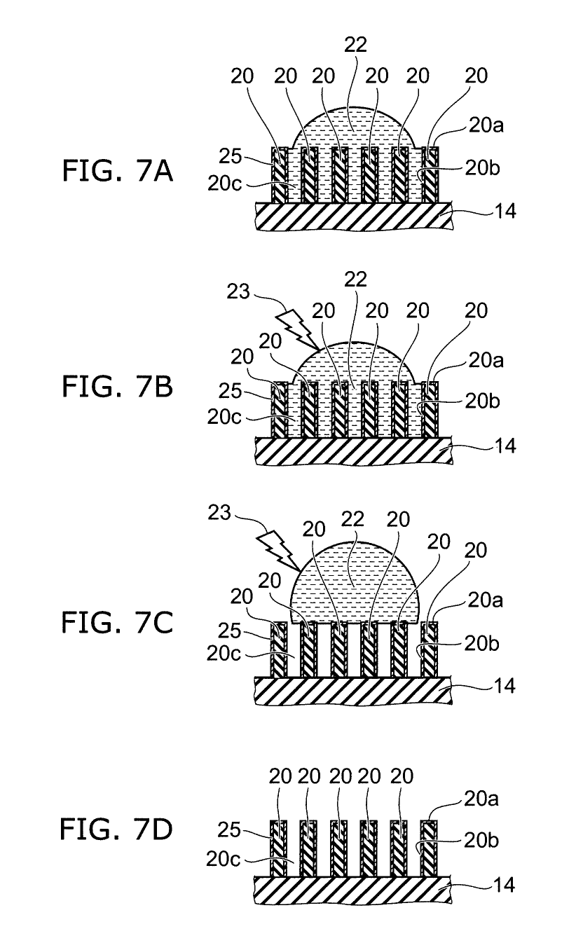

FIGS. 7A to 7D are schematic cross-sectional views illustrating a model in which the water is removed in the method for manufacturing the semiconductor device according to the second embodiment.

This embodiment is an embodiment in which water-repellent processing of the front surface of the semiconductor member 21 is performed after the process of cleaning and prior to the process of rinsing with the purified water.

The content of step S301 and S302 illustrated in FIG. 6 is similar to the content of step S201 and S202 of the first embodiment illustrated in FIG. 3, and a description is therefore omitted.

As illustrated in step S303 of FIG. 6, alcohol rinsing is performed after the rinsing with the purified water to replace the purified water with alcohol, e.g., IPA (isopropyl alcohol).

Subsequently, as illustrated in step S304, water-repellent processing of the front surface of the semiconductor member 21 is performed. For example, the water-repellent processing is performed by forming a water-repellent protective film 25 using a chemical liquid (a second chemical liquid) including a silane coupling agent. In other words, the water-repellent protective film 25 is formed on the front surface of the protruding patterns 20 by causing the silane coupling agent to contact the front surface of the semiconductor member 21. The water-repellent protective film 25 may be formed using a surfactant.

Then, as illustrated in step S305, alcohol rinsing is performed to replace the chemical liquid including the silane coupling agent with alcohol.

Subsequently, as illustrated in step S306, purified water rinsing is performed to replace the alcohol rinse liquid with purified water. By performing step S305 and step S306, the chemical liquid including the silane coupling agent is replaced with the purified water.

The rinsing illustrated in step S306 may be performed using a solution in which alcohol is mixed with purified water or using acidic water in which carbon dioxide or the like is dissolved into purified water. In the case where the silane coupling agent which is directly and easily substituted for water is used in the water-repellent processing illustrated in step S304, the alcohol rinsing illustrated in step S303 and step S305 is omissible.

As illustrated in FIG. 7A, the water 22 remains on the upper surface 20a of the protruding patterns 20 and inside the recesses 20c between the protruding patterns 20. Similarly to FIGS. 5A to 5D, the example illustrated in FIGS. 7A to 7D is but one example of several models in which the water is removed.

Then, as illustrated in FIGS. 7B to 7D and step S307 of FIG. 6, the water 22 in the recesses 20c between the protruding patterns 20 is discharged from the recesses 20c and moves onto the upper surface 20a of the protruding patterns 20 by irradiating the microwaves 23 onto the semiconductor member 21. At this time, because the water-repellent protective film 25 is formed on the front surface of the protruding patterns 20, the water 22 easily moves from between the protruding patterns 20 onto the upper surface 20a of the protruding patterns 20. The water 22 that moves onto the upper surface 20a becomes to the water drops and easily rolls over the upper surface 20a where the water-repellent protective film 25 is formed, and easily drops off the semiconductor member 21. Further, the water 22 that moves onto the upper surface 20a does not easily reenter the recesses 20c where the water-repellent protective film 25 is formed. For example, if a contact angle of 90° or more is obtained due to the water-repellent protective film formation, the water 22 theoretically does not reenter the recesses 20c.

Thus, the water 22 adhered to the semiconductor member 21 is removed.

Subsequently, the water-repellent protective film 25 is removed as illustrated in step S308 of FIG. 6 by, for example, excimer UV processing if necessary.

Effects of this embodiment will now be described.

Because the water-repellent protective film 25 is formed on the upper surface 20a and side surfaces 20b of the protruding patterns 20 in the semiconductor device according to this embodiment, the water remaining in the recesses 20c between the protruding patterns 20 moves easily onto the upper surface 20a when the microwaves are irradiated. The water 22 that moves onto the upper surface 20a easily drops off the semiconductor member 21. Therefore, because the water 22 no longer remains easily in the recesses 20c between the protruding patterns 20, the protruding patterns 20 collapse even less easily. Accordingly, the semiconductor device can be downscaled because the hard mask 15a does not collapse easily even in the case where a hard mask 15a that is fine is formed. Otherwise, the effects of this embodiment are similar to those of the first embodiment described above.

Similar effects can be obtained even without the water-repellent processing if the material of the protruding patterns 20 is highly water-repellent.

### Test Example

A test example will now be described.

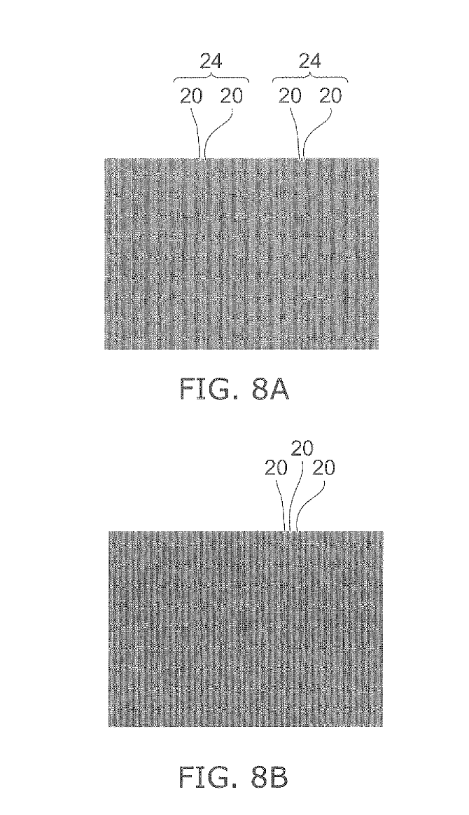

FIGS. 8A and 8B are planar SEM photographs illustrating the protruding patterns of a semiconductor member of the method for manufacturing the semiconductor device. FIG. 8A illustrates protruding patterns that are collapsed; and FIG. 8B illustrates protruding patterns that are not collapsed.

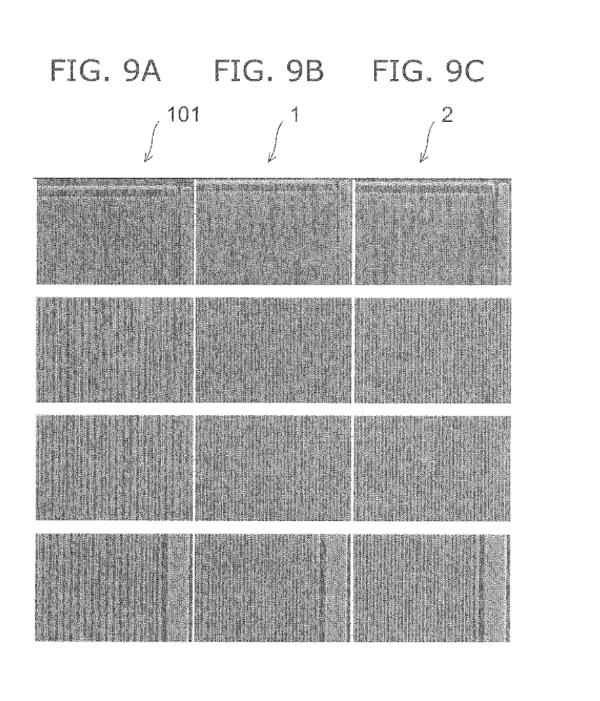

FIGS. 9A to 9C are planar SEM photographs illustrating protruding patterns of four different locations of the upper surface of the semiconductor member of the method for manufacturing the semiconductor device. FIG. 9A illustrates the case of the comparative example of the first embodiment; FIG. 9B illustrates the case where the microwaves of the first embodiment were 200 W; and FIG. 9C illustrates the case where the microwaves of the second embodiment were 200 W.

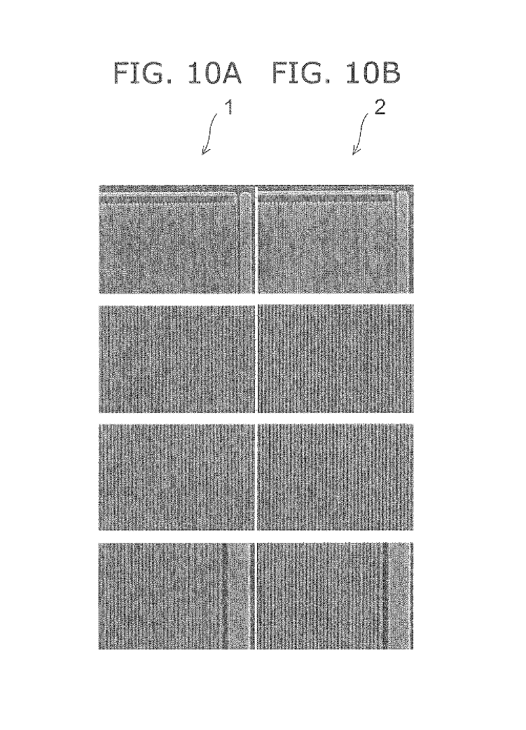

FIGS. 10A and 10B are planar SEM photographs illustrating protruding patterns of four different locations of the upper surface of the semiconductor member of the method for manufacturing the semiconductor device. FIG. 10A illustrates the case where the microwaves of the first embodiment were 1000 W; and FIG. 10B illustrates the case where the microwaves of the second embodiment were 1000 W.

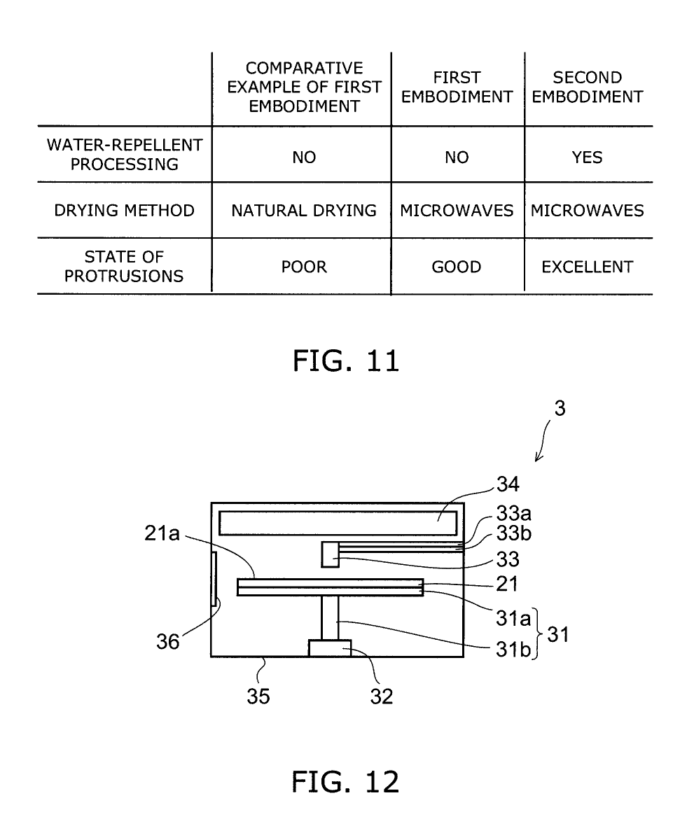

FIG. 11 compares the first embodiment, the second embodiment, and the comparative example of the first embodiment of the method for manufacturing the semiconductor device.

As illustrated in FIG. 8A, when the protruding patterns 20 collapse, two adjacent protruding patterns 20 closely adhere to each other and form a pair 24. On the other hand, the distance between the pairs 24 increases. Thereby, the protruding patterns 20 are in a state in which the protruding patterns 20 that have large spacing coexist with the protruding patterns 20 that are closely adhered.

In the case where the protruding patterns 20 are not collapsed as illustrated in FIG. 8B, the protruding patterns 20 are disposed with substantially uniform spacing.

The semiconductor device 101 according to the comparative example of the first embodiment as illustrated in FIG. 9A was in a state in which the protruding patterns 20 that have large spacing coexist with the protruding patterns 20 that are closely adhered. This illustrates that substantially all of the protruding patterns 20 collapsed.

On the other hand, in the semiconductor device 1 according to the first embodiment as illustrated in FIG. 9B and FIG. 10A, there were more portions where the spacing of the protruding patterns 20 had substantially uniform spacing. This illustrates that the protruding patterns 20 did not collapse easily. Fewer protruding patterns 20 were collapsed for the case where the output of the microwaves was 1000 W than for the case of 200 W.

In the semiconductor device 2 according to the second embodiment as illustrated in FIG. 9C and FIG. 10B, substantially all of the protruding patterns 20 had substantially uniform spacing. This illustrates that substantially none of the protruding patterns 20 were collapsed. Fewer protruding patterns 20 were collapsed for the case where the output of the microwaves was 1000 W than for the case of 200 W.

Comparing the methods for manufacturing the semiconductor devices of this test example as illustrated in FIG. 11, the second embodiment was the most desirable manufacturing method. The first embodiment was the next most desirable manufacturing method. The comparative example of the first embodiment was not desirable as a manufacturing method.

### Third Embodiment

A third embodiment will now be described.

This embodiment is an apparatus for manufacturing a semiconductor device.

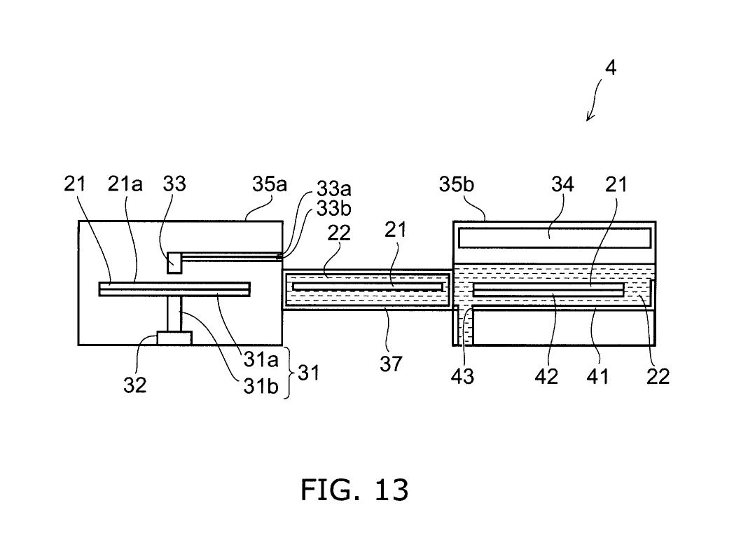

FIG. 12 illustrates the apparatus for manufacturing the semiconductor device according to the third embodiment.

In the manufacturing apparatus 3 according to this embodiment as illustrated in FIG. 12, a base unit 31 is provided as a portion of a drying mechanism. The base unit 31 includes a disc unit 31a which has a disc configuration, and an axial unit 31b extending downward from the central portion of the lower surface of the disc unit 31a. The disc unit 31a is disposed horizontally.

A rotation unit 32 is provided below the base unit 31. The axial unit 31b of the base unit 31 is connected to the rotation unit 32.

A nozzle unit 33 is provided above the base unit 31. The nozzle unit 33 is connected to a pipe 33a of a chemical liquid and a pipe 33b of water. The pipe 33a of the chemical liquid is called the chemical liquid supply unit; and the pipe 33b of the water is called the water supply unit.

A microwave irradiation unit 34 is provided as a portion of the drying mechanism above the base unit 31. A housing, e.g., a chamber 35 made of a metal, is provided to cover the microwave irradiation unit 34, the nozzle unit 33, and the base unit 31. A gate valve 36 is provided in the chamber 35. The gate valve 36 can be open and closed.

An operation of this embodiment, i.e., a method for using the manufacturing apparatus 3 described above, will now be described.

The gate valve 36 of the manufacturing apparatus 3 is opened; and one semiconductor member 21 having a disc configuration which is the processing body is inserted into the interior of the chamber 35 and mounted on the upper surface of the disc unit 31a of the base unit 31. A member having a front surface in which the multiple protruding patterns 20 are formed is used as the semiconductor member 21. Subsequently, the disc unit 31a and the semiconductor member 21 disposed on the disc unit 31a are rotated in the horizontal direction with the central axis of the disc unit 31a as the rotational axis by the axial unit 31b being rotated by the rotation unit 32.

Then, as illustrated in step S201 of FIG. 3, the semiconductor member 21 is cleaned by squirting a chemical liquid from the tip of the nozzle unit 33. The chemical liquid is supplied uniformly to an upper surface 21a of the semiconductor member 21 by the rotation of the disc unit 31a. After an appropriate amount of time, the squirting of the chemical liquid is stopped.

Continuing as illustrated in step S202 of FIG. 3, rinsing is performed by squirting purified water from the tip of the nozzle unit 33. The purified water is supplied uniformly to the upper surface 21a of the semiconductor member 21 by the rotation of the disc unit 31a. Thereby, the chemical liquid on the semiconductor member 21 is replaced with the purified water. After an appropriate amount of time, the squirting of the purified water is stopped.

At this stage as illustrated in FIG. 5A, the semiconductor member 21 is in a state in which the multiple protruding patterns 20 are formed on the upper surface 21a, and the water 22 exists in the recesses 20c between the protruding patterns 20.

Subsequently, as illustrated in step S203 of FIG. 3 and FIG. 5B, the microwaves 23 are irradiated onto the semiconductor member 21 by the microwave irradiation unit 34.

Thereby, as illustrated in FIG. 5C, the water 22 that enters the recesses 20c between the protruding patterns 20 is discharged from the recesses 20c and moves onto the upper surface 20a of the protruding patterns 20. The water 22 that moves onto the upper surface 20a is removed from the semiconductor member 21 by moving toward the end portion of the upper surface 21a of the semiconductor member 21 due to the centrifugal force based on the rotation of the disc unit 31a.

Thus, as illustrated in FIG. 5D, the semiconductor member 21 is dried by removing the water adhered to the semiconductor member 21.

Effects of this embodiment will now be described.

Because the microwave irradiation unit 34 is provided in the apparatus 3 for manufacturing the semiconductor device according to this embodiment, the water 22 in the recesses 20c between the protruding patterns 20 can be discharged from the recesses 20c and moved onto the upper surface 20a of the protruding patterns 20 while suppressing the collapse of the protruding patterns 20. Therefore, the water 22 can be removed while suppressing the collapse of the protruding patterns 20 even in the case where the fine protruding patterns 20 are formed. Thereby, the semiconductor device can be downscaled.

Because the microwave irradiation unit 34 is covered with the chamber 35 that is made of a metal in the manufacturing apparatus 3 according to this embodiment, the microwaves 23 are reflected inside the chamber 35. Thereby, the microwaves 23 can be irradiated efficiently onto the semiconductor member 21.

Because the rotation unit 32 is provided in the manufacturing apparatus 3 according to this embodiment, the water 22 on the upper surface 21a can be removed from the end portion of the semiconductor member 21 by the centrifugal force.

Also, the nozzle unit 33 is provided in the manufacturing apparatus 3. Therefore, the water 22 can be squirted toward the center of the semiconductor member 21. The water 22 can be supplied uniformly to the semiconductor member 21 by being supplied while rotating the rotation unit 32.

The rotation unit 32 may be disposed either inside or outside the chamber 35.

The water-repellent processing of the second embodiment described above may be performed in the manufacturing apparatus 3 of this embodiment. In such a case, as illustrated in step S303 to step S306 of FIG. 6, the purified water and the alcohol for the rinsing and the chemical liquid for the water-repellent processing are supplied from the nozzle unit 33 to the upper surface 21a of the semiconductor member 21.

### Fourth Embodiment

A fourth embodiment will now be described.

FIG. 13 illustrates an apparatus for manufacturing a semiconductor device according to the fourth embodiment.

As illustrated in FIG. 13, two chambers 35a and 35b are provided in the apparatus 4 for manufacturing the semiconductor device according to this embodiment. The base unit 31, the rotation unit 32, and the nozzle unit 33 are disposed in the interior of the chamber 35a. On the other hand, the microwave irradiation unit 34 and a water tank unit 41 are provided in the interior of the chamber 35b. A plate-like unit 42 is provided in the interior of the water tank unit 41. A drainage hole 43 is provided in the bottom surface of the water tank unit 41. A transfer unit 37 is provided between the chamber 35a and the chamber 35b. The transfer unit 37 has a structure that can be sealed.

An operation of this embodiment, i.e., a method for using the manufacturing apparatus 4 described above, will now be described.

First, the transfer unit 37 and the water tank unit 41 are filled with the water 22. Then, one semiconductor member 21 is inserted into the interior of the chamber 35a and mounted on the upper surface of the disc unit 31a of the base unit 31. Subsequently, the disc unit 31a and the semiconductor member 21 disposed on the disc unit 31a are rotated in the horizontal direction with the central axis of the disc unit 31a as the rotational axis by the axial unit 31b being rotated by the rotation unit 32.

Then, as illustrated in step S201 of FIG. 3, the semiconductor member 21 is cleaned by squirting a chemical liquid from the tip of the nozzle unit 33. The chemical liquid is supplied uniformly to the upper surface 21a of the semiconductor member 21 by the rotation of the disc unit 31a. After an appropriate amount of time, the squirting of the chemical liquid is stopped.

Continuing as illustrated in step S202 of FIG. 3, rinsing is performed by squirting purified water from the tip of the nozzle unit 33. The purified water is supplied uniformly to the upper surface 21a of the semiconductor member 21 by the rotation of the disc unit 31a. Thereby, the chemical liquid on the semiconductor member 21 is removed. After an appropriate amount of time, the squirting of the purified water is stopped.

Subsequently, the semiconductor member 21 is sealed in the interior of the transfer unit 37 that is filled with the water 22. The water adheres to the front surface of the semiconductor member 21 sealed in the transfer unit 37. Also, the water exists in the recesses 20c between the protruding patterns 20 of the semiconductor member 21. Then, the semiconductor member 21 is transferred to the interior of the chamber 35b by the transfer unit 37. Continuing, the semiconductor member 21 is mounted on the upper surface of the plate-like unit 42 in the water tank unit 41 while being immersed in the water 22.

Subsequently, the drainage hole 43 of the water tank unit 41 is opened to discharge the water 22 in which the semiconductor member 21 is sealed.

At this stage as illustrated in FIG. 5A, the water 22 is adhered to the front surface of the semiconductor member 21. The multiple protruding patterns 20 are formed on the upper surface 21a of the semiconductor member 21 in a state in which the water 22 exists in the recesses 20c between the protruding patterns 20.

Then, as illustrated in step S203 of FIG. 3 and FIG. 5B, the microwaves 23 are irradiated onto the semiconductor member 21 by the microwave irradiation unit 34.

Thereby, as illustrated in FIG. 5C, the water 22 that enters the recesses 20c between the protruding patterns 20 is discharged from the recesses 20c and moves onto the upper surface 20a of the protruding patterns 20. Then, the water 22 that moves onto the upper surface 20a drops off the upper surface 21a of the semiconductor member 21.

Thus, as illustrated in FIG. 5D, the semiconductor member 21 is dried by removing the water adhered to the semiconductor member 21.

Effects of this embodiment will now be described.

In this embodiment, the rotation unit 32 and the microwave irradiation unit 34 are separately disposed in chambers 35a and 35b. Therefore, the chemical liquid scattering from the disc unit 31a due to the rotation of the rotation unit 32 does not fall on the microwave irradiation unit 34. Therefore, corrosion of the microwave irradiation unit 34 can be prevented.

In this embodiment, the transfer unit 37 that is filled with the water 22 is disposed between the base unit 31 and the microwave irradiation unit 34. Therefore, the semiconductor member 21 can be transferred from the chamber 35a to the chamber 35b while being wet even though the base unit 31 and the microwave irradiation unit 34 are separately disposed in the chambers 35a and 35b. Therefore, the protruding patterns 20 do not collapse due to natural drying of the water 22 remaining in the recesses 20c between the protruding patterns 20 partway through the transferring of the semiconductor member 21.

Otherwise, the effects of this embodiment are similar to those of the third embodiment described above.

The plate-like unit 42 may have a disc configuration; and the plate-like unit 42 and the semiconductor member 21 on the plate-like unit 42 may be rotated with the central axis of the plate-like unit 42 as the rotational axis when irradiating the microwaves 23.

The water-repellent processing of the second embodiment described above may be performed in the manufacturing apparatus 4 of this embodiment. In such a case, the purified water and the alcohol for the rinsing and the chemical liquid for the water-repellent processing are supplied to the upper surface 21a of the semiconductor member 21 from the nozzle unit 33 as illustrated in step S303 to step S306 of FIG. 6.

### Fifth Embodiment

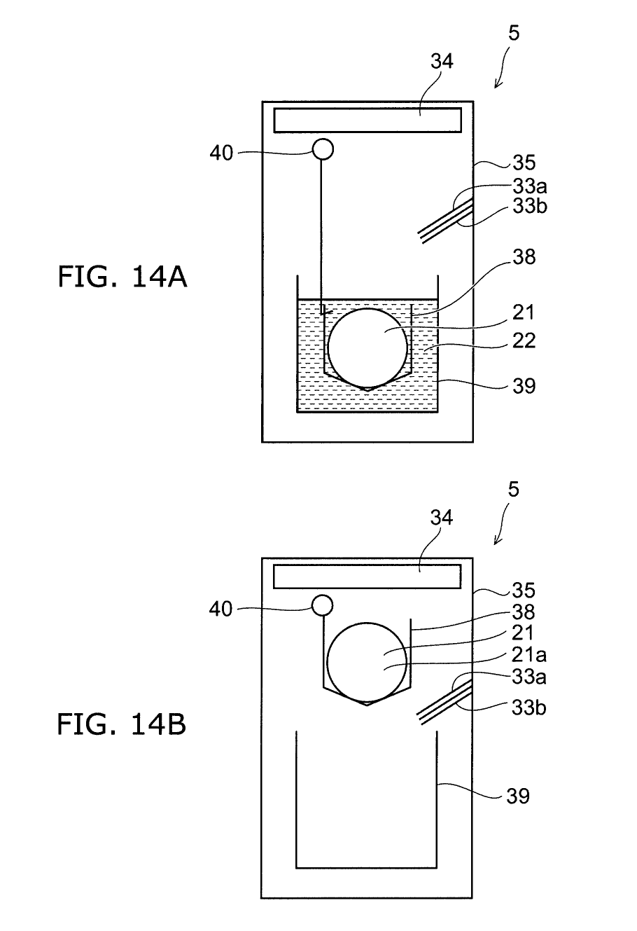

FIGS. 14A and 14B illustrate an apparatus for manufacturing a semiconductor device according to a fifth embodiment.

As illustrated in FIGS. 14A and 14B, the manufacturing apparatus 5 according to this embodiment includes a holder unit 38. The holder unit 38 holds the multiple semiconductor members 21 in a state in which the front surfaces of the multiple semiconductor members 21 are tilted with respect to horizontal, that is, are in a state in which the processing surfaces of the semiconductor members 21 are vertical.

A tank 39 is provided in the manufacturing apparatus 5. The tank 39 is a container that contains the chemical liquid and the purified water. A lift unit 40 is provided as a portion of the drying mechanism in the manufacturing apparatus 5. The lift unit 40 can remove the holder unit 38 from the tank 39 and place the holder unit 38 inside the tank 39.

The microwave irradiation unit 34 is disposed above the tank 39.

An operation of this embodiment, i.e., a method for using the manufacturing apparatus 5 described above, will now be described.

As illustrated in FIG. 14A, the multiple semiconductor members 21 which are the processing bodies are mounted in the holder unit 38. A chemical liquid (not illustrated) is filled into the interior of the tank 39 from the pipe 33a of the chemical liquid which is the chemical liquid supply unit.

Then, as illustrated in step S201 of FIG. 3, the lift unit 40 inserts the holder unit 38 in which the multiple semiconductor members 21 are mounted into the interior of the tank 39 which is filled with the chemical liquid. Thereby, the semiconductor members 21 are cleaned.

Then, after an appropriate amount of time as illustrated in FIG. 14B, the holder unit 38 is lifted from the tank 39 which is filled with the chemical liquid. Then, after the chemical liquid of the interior of the tank 39 is discharged, purified water is filled into the interior of the tank 39 from the pipe 33b of the water which is the water supply unit.

Continuing as illustrated in FIG. 14A and step S202 of FIG. 3, the lift unit 40 inserts the holder unit 38 in which the multiple semiconductor members 21 are mounted into the interior of the tank 39 which is filled with the purified water. Thereby, rinsing is performed to remove the chemical liquid that is on the semiconductor members 21.

Then, after an appropriate amount of time as illustrated in FIG. 14B, the holder unit 38 is lifted from the tank 39 which is filled with the purified water.

At this stage as illustrated in FIG. 5A, the semiconductor members 21 are in a state in which the multiple protruding patterns 20 are formed on the upper surface 21a, and the water 22 exists in the recesses 20c between the protruding patterns 20.

Then, after the purified water filled into the interior of the tank 39 is discharged, as illustrated in FIG. 14B, FIG. 5B, and step S203 of FIG. 3, the microwaves 23 are irradiated by the microwave irradiation unit 34 onto the semiconductor members 21 mounted in the holder unit 38 that is lifted.

Thereby, as illustrated in FIG. 5C, the water 22 that enters the recesses 20c between the protruding patterns 20 is discharged from the recesses 20c and moves onto the upper surface 20a of the protruding patterns 20. The water 22 that moves onto the upper surfaces 20a falls from the front surfaces of the semiconductor members 21.

Thus, as illustrated in FIG. 5D, the semiconductor members 21 are dried by removing the water adhered to the semiconductor members 21.

Effects of this embodiment will now be described.

In the manufacturing apparatus 5 according to this embodiment, the multiple semiconductor members 21 can be processed at one time. For example, fifty of the semiconductor members 21 can be processed simultaneously. Therefore, the manufacturing unit cost of the semiconductor device can be reduced.

In the case where the water-repellent protective film 25 is formed on the front surface of the protruding patterns 20, the upper surfaces of the semiconductor members 21 can be in the state of being tilted with respect to horizontal; and the water 22 pushed out onto the upper surface 20a of the protruding patterns 20 can be removed by gravity.

Because the water 22 in the interior of the tank 39 is discharged when irradiating the microwaves 23, the water 22 inside the tank 39 can be prevented from boiling due to the microwaves 23. Otherwise, the effects of this embodiment are similar to those of the third embodiment described above.

Instead of discharging the water 22 in the interior of the tank 39 when irradiating the microwaves 23, the tank 39 may be shielded from the holder unit 38 such that the microwaves are not transmitted. Thereby, the water 22 inside the tank 39 can be prevented from boiling due to the microwaves 23.

The water-repellent processing of the second embodiment described above may be performed in the manufacturing apparatus 5 of this embodiment. In such a case, the purified water and the alcohol for the rinsing and the chemical liquid for the water-repellent processing are sequentially filled into the interior of the tank 39 as illustrated in step S303 to step S306 of FIG. 6 and the holder unit 38 is removed from and placed inside the tank 39 which is filled with these chemical liquids.

### Sixth Embodiment

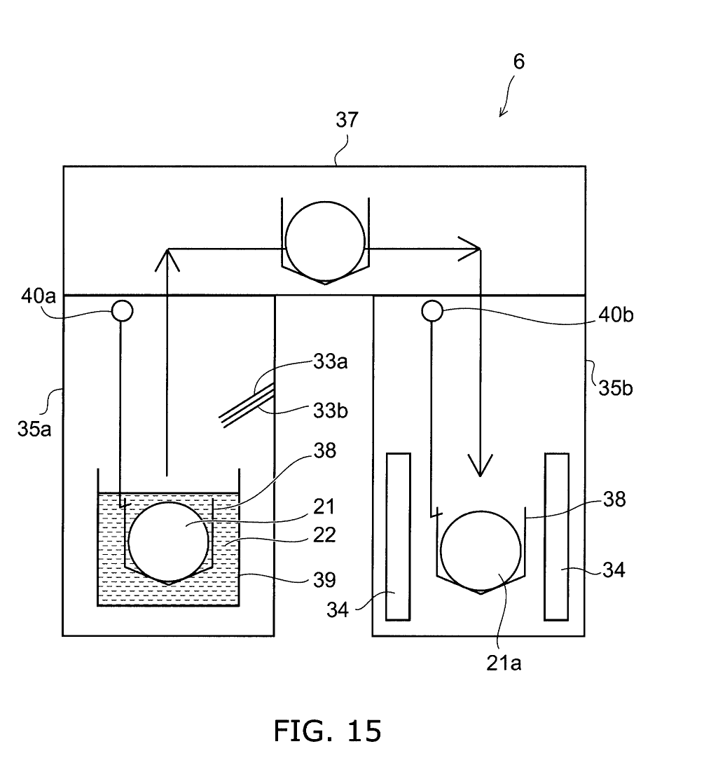

FIG. 15 illustrates an apparatus for manufacturing a semiconductor device according to a sixth embodiment.

As illustrated in FIG. 15, the two chambers 35a and 35b are provided in the manufacturing apparatus 6 according to this embodiment. The tank 39 and a lift unit 40a are provided in the interior of the chamber 35a. On the other hand, two microwave irradiation units 34 and a lift unit 40b are provided in the interior of the chamber 35b. The two microwave irradiation units 34 are disposed on two sides of the space inside the chamber 35b. The transfer unit 37 is provided between the chamber 35a and the chamber 35b. At least one of the temperature, the humidity, and the pressure of the interior of the transfer unit 37 is adjustable such that the semiconductor members 21 do not undergo natural drying.

An operation of this embodiment, i.e., a method for using the manufacturing apparatus 6 described above, will now be described.

The multiple semiconductor members 21 are mounted in the holder unit 38. A chemical liquid is filled into the interior of the tank 39.

Then, inside the chamber 35a as illustrated in step S201 of FIG. 3, the lift unit 40a inserts the holder unit 38 in which the multiple semiconductor members 21 are mounted into the interior of the tank 39 which is filled with the chemical liquid. Thereby, the semiconductor members 21 are cleaned. After an appropriate amount of time, the lift unit 40a lifts the holder unit 38 from the interior of the tank 39. Then, the chemical liquid filled into the interior of the tank 39 is discharged. Subsequently, purified water is filled into the interior of the tank 39.

Continuing as illustrated in step S202 of FIG. 3, the lift unit 40a inserts the holder unit 38 in which the multiple semiconductor members 21 are mounted into the interior of the tank 39 which is filled with the purified water. Thereby, rinsing is performed to remove the chemical liquid on the semiconductor members 21 using the purified water. After an appropriate amount of time, the lift unit 40a lifts the holder unit 38 in which the multiple semiconductor members 21 are mounted from the interior of the tank 39. The holder unit 38 that is lifted is moved to the transfer unit 37. In the transfer unit 37, water is adhered to the front surfaces of the semiconductor members 21. The water exists in the recesses 20c between the protruding patterns 20 of the semiconductor members 21. Then, the holder unit 38 is moved inside the chamber 35b via the transfer unit 37. Then, the lift unit 40b disposes the holder unit 38 in which the semiconductor members 21 are mounted between the two microwave irradiation units 34.

At this stage as illustrated in FIG. 5A, the water 22 is adhered to the front surfaces of the semiconductor members 21. The semiconductor members 21 are in a state in which the multiple protruding patterns 20 are formed on the upper surfaces 21a and the water 22 exists in the recesses 20c between the protruding patterns 20.

Then, as illustrated in step S203 of FIG. 3 and FIG. 5B, the microwaves 23 are irradiated onto the semiconductor members 21.

Thereby, as illustrated in FIG. 5C, the water 22 that enters the recesses 20c between the protruding patterns 20 is discharged from the recesses 20c and moves onto the upper surface 20a of the protruding patterns 20. The water 22 that moves onto the upper surfaces 20a falls from the front surfaces of the semiconductor members 21.

Thus, as illustrated in FIG. 5D, the semiconductor members 21 are dried by removing the water adhered to the semiconductor members 21.

Effects of this embodiment will now be described.

In the manufacturing apparatus 6 according to this embodiment, the tank 39 and the microwave irradiation unit 34 are separately disposed in the chambers 35a and 35b. Therefore, the water 22 in the interior of the tank 39 can be prevented from boiling due to the microwaves 23.

In the manufacturing apparatus 6, the transfer unit 37 is disposed between the chamber 35a in which the tank 39 is disposed and the chamber 35b in which the microwave irradiation unit 34 is disposed. Thus, optionally adjusting at least one of the temperature, the humidity, and the pressure in the transfer unit 37, the semiconductor members 21 can be transferred from the chamber 35a to the chamber 35b while being wet even in the case where the tank 39 and the microwave irradiation unit 34 are separately disposed in the interiors of the chambers 35a and 35b. Therefore, the protruding patterns 20 do not collapse due to the water in the recesses 20c between the protruding patterns 20. Thereby, the semiconductor device can be downscaled because the collapse of the protruding patterns 20 can be suppressed even in the case where the fine protruding patterns 20 are formed. Otherwise, the effects of this embodiment are similar to those of the third embodiment described above.

The water-repellent processing of the second embodiment described above may be performed in the manufacturing apparatus 6 of this embodiment. In such a case, the purified water and the alcohol for the rinsing and the chemical liquid for the water-repellent processing are sequentially filled into the interior of the tank 39 as illustrated in step S303 to step S306 of FIG. 6 and the holder unit 38 is removed from and placed inside the tank 39 which is filled with these chemical liquids.

According to the embodiments described above, a method and an apparatus for manufacturing a semiconductor device that can be downscaled can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor device, comprising:
rinsing a substrate with water, a plurality of protruding patterns being formed on the substrate; and
drying the substrate by removing water from a recess between the protruding patterns by irradiating microwaves.

2. The method according to claim 1, further comprising cleaning the substrate including the plurality of protruding patterns with a chemical liquid prior to the rinsing.

3. The method according to claim 1, further comprising performing water-repellent processing of a front surface of the protruding patterns of the substrate,
the rinsing including rinsing the substrate processed by the water-repellent processing.

4. The method according to claim 1, wherein the protruding patterns include a hard mask.

5. The method according to claim 2, wherein the chemical liquid of the cleaning includes an aqueous solution containing hydrogen peroxide.

6. The method according to claim 1, wherein a frequency of the microwaves of the drying is 400 MHz to 25 GHz.

7. The method according to claim 3, wherein the performing of the water-repellent processing includes using a chemical liquid including a silane coupling agent.

8. The method according to claim 3, wherein the performing of the water-repellent processing includes using a surfactant.

9. The method according to claim 3, wherein the performing of the water-repellent processing includes forming a water-repellent protective film on the front surface.

10. An apparatus for manufacturing a semiconductor device, comprising:
a chemical liquid supply unit configured to supply a chemical liquid to a processing body to clean the processing body;
a water supply unit configured to supply water to the processing body to rinse the processing body; and
a drying mechanism configured to remove water from a front surface of the processing body, the drying mechanism including a microwave irradiation unit configured to irradiate microwaves onto the processing body.

11. The apparatus according to claim 10, further comprising:
a first chamber, the chemical liquid supply unit and the water supply unit being disposed in the first chamber; and
a second chamber, the microwave irradiation unit being disposed in the second chamber.

12. The apparatus according to claim 11, further comprising a transfer unit configured to transfer the processing body between the first chamber and the second chamber, the transfer unit being configured to transfer the processing body in a state of water being adhered to the front surface of the processing body.

13. The apparatus according to claim 10, further comprising a housing covering the microwave irradiation unit, the housing being made of a metal.

14. The apparatus according to claim 10, further comprising a base unit configured to hold the processing body, the base unit being rotatable in a horizontal direction.

15. The apparatus according to claim 10, further comprising a nozzle unit configured to squirt the chemical liquid and the water toward the processing body.

16. The apparatus according to claim 15, wherein the nozzle unit is also configured to supply to the processing body a chemical liquid for water-repellent processing of the front surface of the processing body.

17. The apparatus according to claim 12, wherein the transfer unit is configured to be filled with water.

18. The apparatus according to claim 10, further comprising:
a holder unit configured to hold a plurality of the processing bodies in a state of front surfaces of the plurality of the processing bodies being tilted with respect to horizontal; and
a tank configured to contain the chemical liquid and the water.

19. The apparatus according to claim 18, further comprising a lift unit configured to remove the holder unit from the tank and place the holder unit inside the tank.

20. The apparatus according to claim 12, wherein at least one of a temperature, a humidity, and a pressure are adjustable in the transfer unit.
